(19) United States
(12) Patent Application Publication
(10) Pub. No.: US 2014/0103956 A1
(43) Pub. Date: Apr. 17, 2014

(54) POWER SUPPLY DETECTION CIRCUIT AND METHOD

(71) Applicant: HON HAI PRECISION INDUSTRY CO., LTD., New Taipei (TW)

(72) Inventors: HSIANG-PIN TSENG, New Taipei (TW); MIN-WEI LEE, New Taipei (TW)

(73) Assignee: HON HAI PRECISION INDUSTRY CO., LTD., New Taipei (TW)

(21) Appl. No.: 13/902,282

(22) Filed: May 24, 2013

(30) Foreign Application Priority Data
Oct. 16, 2012 (TW) 101138021

(51) Int. Cl. G01R 31/40

(52) U.S. Cl. CPC G01R 31/40
USPC 324/764.01

(57) ABSTRACT

A power supply detection circuit includes a controller including a power module for supplying an input voltage to a to-be-tested power supply unit, a controlling module, a signal module, and a detection module, a resistor, and a MOSFET. A first end of the resistor connects an output end of the power supply unit. A second end of the resistor connects to the MOSFET. The MOSFET connects to the signal module. The detection module connects the output end. The control module controls the signal module to generate a pulse signals. The MOSFET is turned on to connect the resistor to the power supply unit to generate a fast-rising current when the pulse signal is in a high level. The detection module detects an output voltage of the output end, to confirm whether the output voltage is equal to the input voltage. This patent further discloses a power supply detection method.

### BACKGROUND

1. Technical Field

The present disclosure relates to detection circuits and methods, and particularly to a power supply detection circuit and method.

2. Description of Related Art

A number of properties should be tested and verified before a power supply is shipped. Especially a load response detecting a sudden load connection of the power supply to the load from the sudden rise in current. Currently a current rising rate of a testing circuit currently is not quick enough to accurately test and verify the response of the power supply. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of one embodiment of a power supply detection circuit.

FIG. 2 is a flow chart of one embodiment of a power supply detection method.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

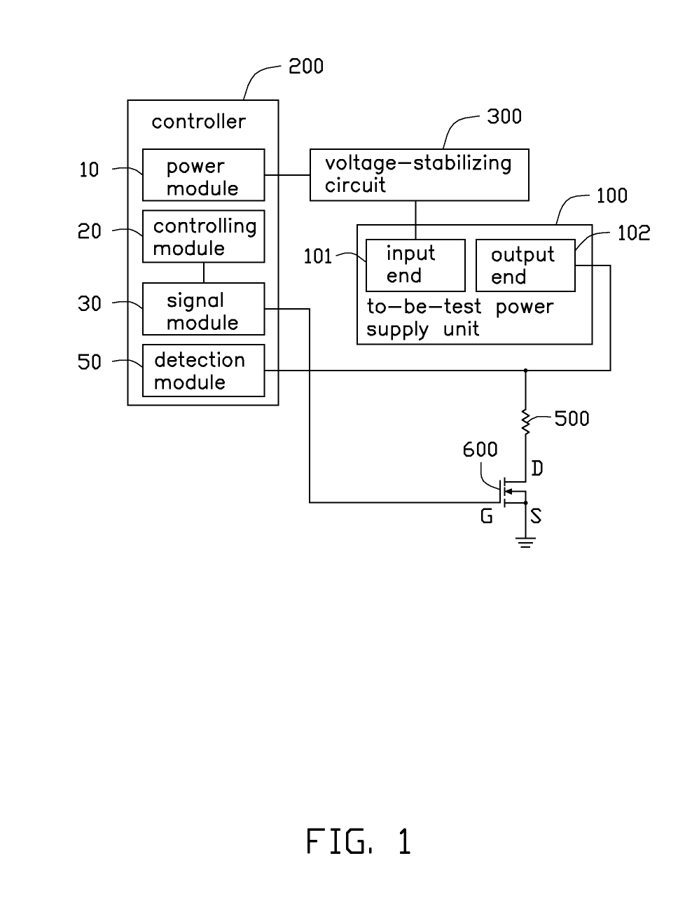

FIG. 1 shows a power supply detection circuit in accordance with an embodiment. The power supply detection circuit is for detecting a to-be-tested power supply unit 100 and includes a controller 200, a voltage-stabilizing circuit 300, a resistor 500, and a MOSFET 600.

The to-be-tested power supply unit 100 includes an input end 101 and an output end 102.

The controller 200 includes a power module 10, a controlling module 20, a signal module 30, and a detection module 50.

The power module 10 connects to the input end 101 via the voltage-stabilizing circuit 300, to input a stable input voltage.

The controlling module 20 connects to the signal module 30 and is used for controlling the signal module 30 to generate a plurality of pulse signals with different duty cycles or different frequencies. The parameters of the plurality of pulse signals are combinations of each of the different duty cycles and each of the different frequencies. In one embodiment, the different duty cycles are 25/75, 50/50, and 75/25, the different frequencies are 1 KHz, 10 KHz, 100 KHz, and 1 MHz, and the parameters of the plurality of pulse signals are 25/75 duty cycle, and 1 KHz frequency; 25/75 duty cycle, and 10 KHz frequency; 25/75 duty cycle, and 100 KHz frequency; 25/75 duty cycle, and 1 MHz frequency; 50/50 duty cycle, and 1 KHz frequency; 50/50 duty cycle, and 10 KHz frequency; 50/50 duty cycle, and 100 KHz frequency; 50/50 duty cycle, and 1 MHz frequency; 75/25 duty cycle, and 1 KHz frequency; 75/25 duty cycle, and 10 KHz frequency; 75/25 duty cycle, and 100 KHz frequency; and 75/25 duty cycle, and 1 MHz frequency. Each of the plurality of pulse signals keeps a fixed time. In one embodiment, the fixed time is 30s.

The MOSFET 600 includes a gate terminal G, a drain terminal D, and a source terminal S.

A first end of the resistor 500 connects to the output end of the to-be-tested power supply unit 100. A second end of the resistor 500 connects to the drain terminal D. In one embodiment, the resistor 500 is a cement resistor. The resistor 500 can be composed of multiple cement resistors in parallel according to need.

The source terminal S is grounded.

The gate terminal D connects to the signal module 30, to receive the plurality of pulse signals from the signal module 30. The MOSFET 600 is turned on when the pulse signals are high level and turned off when the pulse signals are low level. When the MOSFET 600 is turned on, the to-be-tested power supply unit 100 electronically connects the resistor 500. A circuit is defined by the voltage-stabilizing circuit 300, the to-be-tested power supply unit 100, the resistor 500, and the controller 200, and the circuit generates a fast-rising dynamic current.

The output end 102 of the to-be-tested power supply unit 100 connects the detection module 50, to feedback an output voltage to the detection module 50. The detection module 50 detects the output voltage in real time and displays the output voltage in a display (not shown) to confirm whether the output voltage is equal to the input voltage.

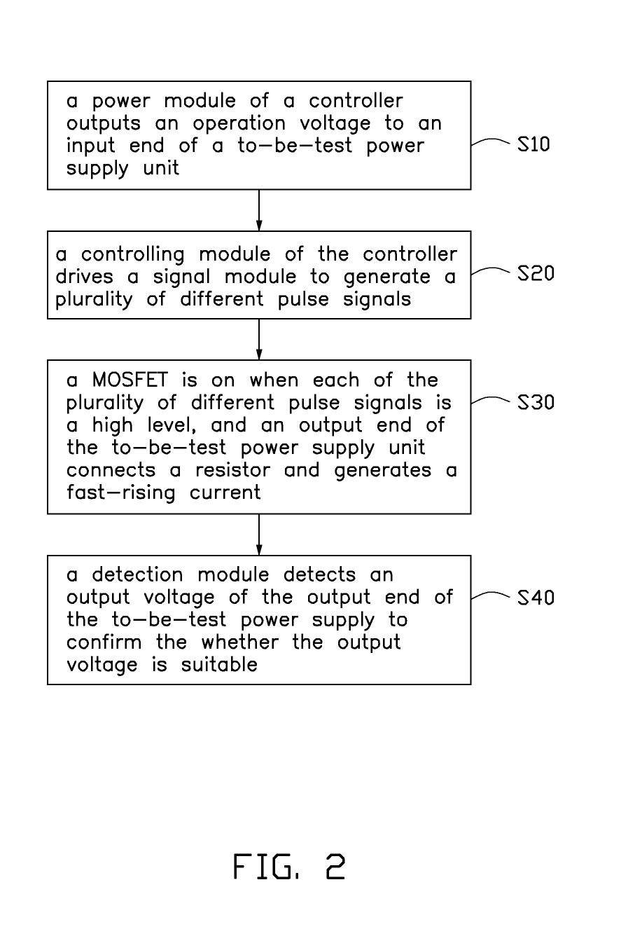

FIG. 2 shows a power supply detection method in accordance with an embodiment. The power supply detection method includes the following steps:

Step S10: the power module 10 supplies the input voltage to the input end of the to-be-tested power supply unit 100.

Step S20: the controlling module 20 drives the signal module 30 to generate the plurality of different pulse signals.

Step S30: the MOSFET is turned on when each of the plurality of different pulse signals is in a high level, and the output end of the to-be-tested power supply unit connects a resistor and generates a fast-rising current.

Step S40: the detection module 50 detects an output voltage of the output end of the to-be-tested power supply unit 100 to confirm whether the output voltage is equal to the input voltage.

Each of the plurality of different pulse signals has a different duty cycle or different frequency from other pulse signals. Each of the plurality of different pulse signals keeps a same time. In one embodiment, the keeping time is 30s. The step S20 includes that the controlling module 20 decides whether the keeping time of one of the plurality of different pulse signals is 30s. If yes, the controlling module 20 controls the signal module 30 to generate a next pulse signal. If no, the controlling module 20 controls the signal module 30 to keep the current pulse signal.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. A power supply detection circuit, for detecting a to-be-tested power supply unit, comprising:
a controller comprising a power module configured for supplying an input voltage to the to-be-tested power supply unit, a controlling module, a signal module, and a detection module;
a resistor; and
a MOSFET;
wherein a first end of the resistor connects to an output end of the to-be-tested power supply unit, and a second end of the resistor connects to the MOSFET; the MOSFET connects to the signal module; the detection module connects to the output end of the to-be-tested power supply unit; the control module controls the signal module to generate a plurality of pulse signals; the MOSFET is turned on to connect the resistor to the to-be-tested power supply unit to generate a fast-rising current when each of the plurality of pulse signals is in a high level; and the detection module detects an output voltage of the output end of the to-be-tested power supply unit, to confirm whether the output voltage is equal to the input voltage.

2. The power supply detection circuit of claim 1, wherein the resistor is a cement resistor.

3. The power supply detection circuit of claim 1, wherein each of the plurality of pulse signals has a different duty cycle or different frequency from other of the plurality of pulse signals.

4. The power supply detection circuit of claim 1, wherein each of the plurality of pulse signals keeps 30s.

5. The power supply detection circuit of claim 1, wherein the MOSFET includes a gate terminal, a source terminal, and a drain terminal; the signal module connects to the gate terminal; the second end of the resistor connects to the drain terminal; and the source terminal is grounded.

6. A power supply detection method, for detecting a to-be-tested power supply unit, comprising below steps:
supplying an input voltage to an input end of the to-be-tested power supply unit by a power module;
driving a signal module by a controlling module to generate a plurality of different pulse signals;
turning on a MOSFET to connect an output end of the to-be-tested power supply unit to a resistor to generate a fast-rising current when each of the plurality of different pulse signals is in a high level;
detecting an output voltage of the output end of the to-be-tested power supply unit by a detection module to confirm whether the output voltage is equal to the input voltage.

7. The power supply detection method of claim 6, wherein the resistor is a cement resistor.

8. The power supply detection method of claim 6, wherein each of the plurality of different pulse signals has a different duty cycle or different frequency from other of the plurality of different pulse signals.

9. The power supply detection method of claim 6, wherein each of the plurality of different pulse signals keeps 30s.

10. The power supply detection method of claim 6, wherein the driving the signal module comprises the controlling module deciding whether each of the plurality of different pulse signals keeps to 30s; when yes, the controlling module controls the signal module to generate a next of the plurality of different pulse signals; when no, the controlling module controls the signal module to keep currently pulse signal.

11. A power supply detection method, for detecting a to-be-tested power supply unit, comprising below steps:
supplying an input voltage to an input end of the to-be-tested power supply unit by a power module;
driving a signal module by a controlling module to generate a plurality of different pulse signals and deciding whether each of the plurality of different pulse signals keeps to 30s; if yes, the controlling module controls the signal module to generate a next of the plurality of different pulse signals; if no, the controlling module controls the signal module to keep currently pulse signal
turning on a MOSFET to connect an output end of the to-be-tested power supply unit to a resistor to generate a fast-rising current when each of the plurality of different pulse signals is in a high level;
detecting an output voltage of the output end of the to-be-tested power supply unit by a detection module to confirm whether the output voltage is equal to the input voltage.

12. The power supply detection method of claim 11, wherein the resistor is a cement resistor.

13. The power supply detection method of claim 11, wherein each of the plurality of different pulse signals has a different duty cycle or different frequency from other of the plurality of different pulse signals.
